(19) United States
(12) Patent Application Publication
(10) Pub. No.: US 2026/0321539 A1
(43) Pub. Date: Oct. 15, 2026

(54) MULTI-CHARGED PARTICLE BEAM WRITING METHOD, AND MULTI-CHARGED PARTICLE BEAM WRITING APPARATUS

(71) Applicant: NuFlare Technology, Inc., Yokohama-shi (JP)

(72) Inventor: Hiroshi MATSUMOTO, Yokohama-shi (JP)

(73) Assignee: NuFlare Technology, Inc., Yokohama-shi (JP)

(21) Appl. No.: 19/578,512

(22) Filed: Mar. 25, 2026

(30) Foreign Application Priority Data
Apr. 15, 2025 (JP) 2025-067077

(51) Int. Cl. H01J 37/302; H01J 37/317

(52) U.S. Cl. CPC H01J 37/3026; H01J 37/3177

(57) ABSTRACT

According to one aspect of the present invention, a multi-charged particle beam writing method includes performing allocation, with respect to each irradiation-unit-region-set of a plurality of irradiation-unit-region-sets, in order that one of a dose and an irradiation time of an irradiation unit region to which one group of a plurality of groups has been assigned can become more than one of a dose and an irradiation time of an irradiation unit region, in a same irradiation-unit-region-set, to which another group of the plurality of groups has been assigned, in such a manner that at least a part of the one of the dose and the irradiation time of the irradiation unit region to which the another group has been assigned is allocated to the irradiation unit region to which the one group has been assigned.

### CROSS-REFERENCE TO RELATED APPLICATION

This application is based upon and claims the benefit of priority from prior Japanese Patent Application No. 2025-067077 filed on Apr. 15, 2025 in Japan, the entire contents of which are incorporated herein by reference.

### BACKGROUND OF THE INVENTION

### Field of the Invention

Embodiments of the present invention relate to a multi-charged particle beam writing method and a multi-charged particle beam writing apparatus.

### Description of Related Art

The lithography technique which advances miniaturization of semiconductor devices is extremely important as a unique process in which patterns are formed in semiconductor manufacturing. In recent years, with high integration of LSI, the line width (critical dimension) necessary for semiconductor device circuits is decreasing year by year. The electron beam writing technique, which intrinsically has excellent resolution, is used for writing or “drawing” patterns on a wafer exposure mask, wafer, and the like with electron beams.

For example, as a known example of employing the electron beam writing technique, there is a writing apparatus using multiple electron beams. Since writing with multiple electron beams can apply a lot of beams at a time, the writing throughput can be greatly increased compared to writing with a single electron beam. For example, a writing apparatus employing the multiple-beam system forms multiple beams by letting an electron beam emitted from an electron gun pass through a mask having a plurality of holes, performs blanking control for each beam, reduces each unblocked beam to generate a reduced mask image by an optical system, and deflects, by a deflector, a reduced beam to be applied to a desired position on a target object or “sample”.

With recent trend of miniaturization of patterns, the writing process has been shifted to a low sensitivity resist. As the resist sensitivity becomes lower, irradiation with a higher dose becomes necessary along with it. However, in the multi-beam writing, if the total beam current becomes large, beam blur occurs due to the Coulomb effect, which degrades the resolution performance.

Therefore, it is desirable to reduce an average ON-beam current during beam irradiation at each shot cycle, by decreasing the number of beams simultaneously becoming ON.

There is disclosed a case where a beam array is divided lengthwise into two, and when the maximum modulation rate in a sub beam array in the upper half region R1 is larger than that in a sub beam array in the lower half region R2, using weights w1 and w2 whose average is 1, the weight w1 which decreases a modulation rate is weighted to the upper half region R1, and the weight w2 which increases a modulation rate is weighted to the lower half region R2, and then, multi-pass multiple writing whose number of passes is two is performed (e.g., refer to Japanese Patent Application Laid-open (JP-A) No. 2021-015881). Thereby, the maximum modulation rate in the beam array is decreased, so that writing time is reduced. However, since the method described above makes the irradiation time of the regions R1 and R2 close to be equalized, the number of beams simultaneously becoming ON is not reduced, and therefore, an average ON-beam current is not reduced.

### BRIEF SUMMARY OF THE INVENTION

According to one aspect of the present invention, a multi-charged particle beam writing method includes
assigning one of a plurality of groups to each of a plurality of irradiation unit regions, which are unit regions to be irradiated with each beam of multiple charged particle beams, obtained by dividing a writing region of a target object, in such a manner that irradiation unit regions, which are in advance set to form a same irradiation-unit-region-set of a plurality of irradiation-unit-region-sets, belong to different groups, and that irradiation unit regions to be irradiated with each shot of the multiple charged particle beams include irradiation unit regions of different groups;
performing allocation, with respect to each irradiation-unit-region-set of the plurality of irradiation-unit-region-sets, in order that one of a dose and an irradiation time of an irradiation unit region to which one group of the plurality of groups has been assigned can become more than one of a dose and an irradiation time of an irradiation unit region, in a same irradiation-unit-region-set, to which another group of the plurality of groups has been assigned, in such a manner that at least a part of the one of the dose and the irradiation time of the irradiation unit region to which the another group has been assigned is allocated to the irradiation unit region to which the one group has been assigned; and
writing a pattern on the target object using the multiple charged particle beams in such a manner that the plurality of irradiation unit regions are irradiated with a charged particle beam having one of a dose and an irradiation time defined by the allocation.

According to another aspect of the present invention, a multi-charged particle beam writing apparatus includes
a group assignment processing circuit configured to assign one of a plurality of groups to each of a plurality of irradiation unit regions, which are unit regions to be irradiated with each beam of multiple charged particle beams, obtained by dividing a writing region of a target object, in such a manner that irradiation unit regions, which are in advance set to form a same irradiation-unit-region-set of a plurality of irradiation-unit-region-sets, belong to different groups, and that irradiation unit regions to be irradiated with each shot of the multiple charged particle beams include irradiation unit regions of different groups;
an allocation circuit configured to perform allocation, with respect to each irradiation-unit-region-set of the plurality of irradiation-unit-region-sets, in order that one of a dose and an irradiation time of an irradiation unit region to which one group of the plurality of groups has been assigned can become more than one of a dose and an irradiation time of an irradiation unit region, in a same irradiation-unit-region-set, to which another group of the plurality of groups has been assigned, in such a manner that at least a part of the one of the dose and the irradiation time of the irradiation unit region to which the another group has been assigned is allocated to the irradiation unit region to which the one group has been assigned; and
a writing mechanism configured to write a pattern on the target object using the multiple charged particle beams in such a manner that the plurality of irradiation unit regions are irradiated with a charged particle beam having one of a dose and an irradiation time defined by the allocation.

### BRIEF DESCRIPTION OF THE DRAWINGS

FIG. 1 is a schematic diagram of a configuration of a writing apparatus according to a first embodiment;

FIG. 2 is a conceptual diagram showing a configuration of a shaping aperture array substrate according to the first embodiment;

FIG. 3 is a sectional view showing a configuration of a blanking aperture array mechanism according to the first embodiment;

FIG. 4 is a conceptual diagram for explaining an example of a writing operation according to the first embodiment;

FIG. 5 is an illustration showing an example of an irradiation region of multiple electron beams and a writing target pixel according to the first embodiment;

FIG. 6 is an illustration showing an example of an irradiation time of one shot of multiple electron beams according to a comparative example of the first embodiment;

FIG. 7 is a flowchart showing an example of main steps of a writing method according to the first embodiment;

FIG. 8 is an illustration showing an example of assigning a group to a pixel according to the first embodiment;

FIG. 9 is an illustration showing an example of an irradiation time of one shot of multiple electron beams according to the first embodiment;

FIG. 10 is an illustration showing an example of a dose distribution before allocation according to the first embodiment;

FIG. 11 is an illustration showing an example of a dose distribution after allocation according to the first embodiment;

FIG. 12 is an illustration showing an example of an accumulated dose distribution to the resist after allocation according to the first embodiment;

FIG. 13 is an illustration showing an example of a dose distribution in the x direction after allocation according to the first embodiment;

FIG. 14 is an illustration showing an example of a dose distribution in the y direction after allocation according to the first embodiment;

FIG. 15 is an illustration for explaining an example of a multi-beam writing operation according to the first embodiment;

FIG. 16 is an illustration showing an example of assignment of groups to pixels according to a second embodiment;

FIG. 17 is an illustration showing an example of an irradiation time of one shot of multiple electron beams according to the second embodiment;

FIG. 18 is an illustration showing an example of a dose distribution after allocation according to the second embodiment;

FIG. 19 is an illustration showing an example of an accumulated dose distribution to resist after allocation according to the second embodiment;

FIG. 20 is an illustration showing an example of a dose distribution in the x direction after allocation according to the second embodiment;

FIG. 21 is an illustration showing an example of a dose distribution in the y direction after allocation according to the second embodiment;

FIG. 22 is an illustration showing an example of stripe layers of passes of multiple writing (multiple pass writing) according to a third embodiment;

FIG. 23 is an illustration showing an example of an assignment of a group to a pixel according to the third embodiment;

FIG. 24 is an illustration showing another example of an assignment of a group to a pixel according to the third embodiment;

FIG. 25 is an illustration showing an example of an irradiation time of one shot of multiple electron beams according to a fourth embodiment; and

FIG. 26 is an illustration showing an example of an irradiation time of one shot of multiple electron beams according to a fifth embodiment.

### DETAILED DESCRIPTION OF THE INVENTION

Embodiments of the present invention provide a writing method and writing apparatus that can reduce an average ON-beam current during beam irradiation at each shot cycle.

Embodiments of the present invention describe multiple electron beams as an example of multiple charged particle beams. The charged particle beam is not limited to the electron beam, and other charged particle beams such as an ion beam may also be used.

### First Embodiment

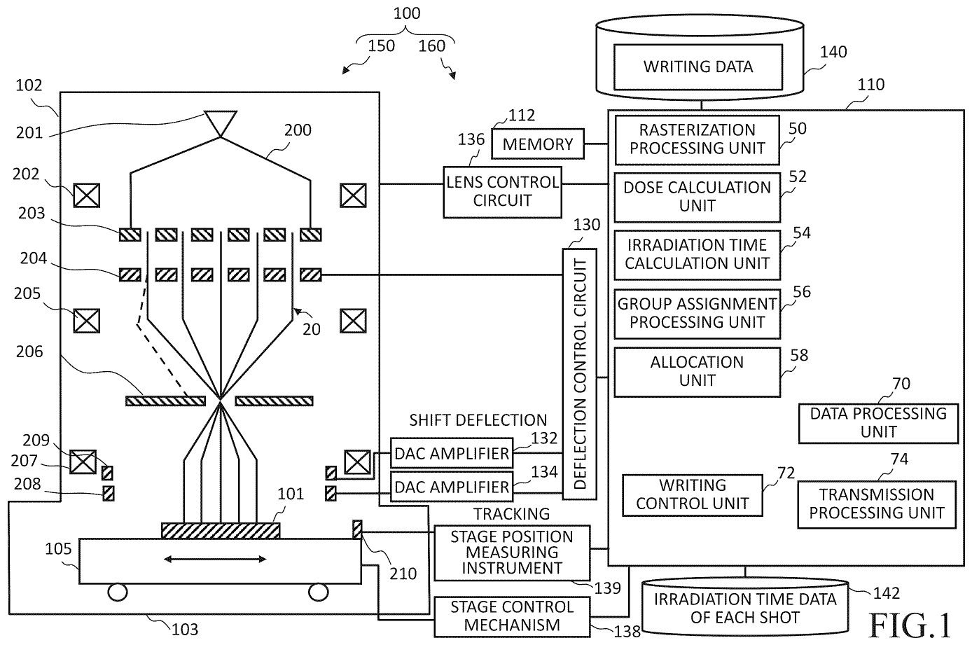

FIG. 1 is a schematic diagram of a configuration of a writing or “drawing” apparatus according to a first embodiment. As shown in FIG. 1, a writing apparatus 100 includes a writing mechanism 150 and a control system circuit 160. The writing apparatus 100 is an example of a multi-charged particle beam writing apparatus and an example of a multi-charged particle beam exposure apparatus. Also, the writing apparatus 100 is an example of a raster beam writing apparatus. The writing mechanism 150 includes an electron optical column 102 (electron beam column) and a writing chamber 103. In the electron optical column 102, there are disposed an electron gun 201, an illumination lens 202, a shaping aperture array substrate 203, a blanking aperture array mechanism 204, a reducing lens 205, a limiting aperture substrate 206, an objective lens 207, a main deflector 208, and a sub deflector 209.

In the writing chamber 103, an XY stage 105 is disposed. On the XY stage 105, there is placed a target object or “sample” 101, such as a mask, serving as a writing target substrate when writing (exposure) is performed. For example, the target object 101 is an exposure mask used in fabricating semiconductor devices, or a semiconductor substrate (silicon wafer) for fabricating semiconductor devices. The target object 101 may be a mask blank on which resist has been applied and nothing has yet been written. On the XY stage 105, a mirror 210 for measuring the position of the XY stage 105 is placed.

The control system circuit 160 includes a control computer 110, a memory 112, a deflection control circuit 130, digital-analog converter (DAC) amplifier units 132 and 134, a lens control circuit 136, a stage control mechanism 138, a stage position measuring instrument 139, and storage devices 140 and 142 such as magnetic disk drives. The control computer 110, the memory 112, the deflection control circuit 130, the lens control circuit 136, the stage control mechanism 138, the stage position measuring instrument 139, and the storage devices 140 and 142 are connected to each other through a bus (not shown). The DAC amplifier units 132 and 134, and the blanking aperture array mechanism 204 are connected to the deflection control circuit 130. The sub deflector 209 is composed of at least four electrodes (or “at least four poles”), and controlled by the deflection control circuit 130 through the DAC amplifier 132 disposed for each electrode. The main deflector 208 is composed of at least four electrodes (or “at least four poles”), and controlled by the deflection control circuit 130 through the DAC amplifier 134 disposed for each electrode. Lenses, such as the illumination lens 202, the reducing lens 205, and the objective lens 207 are controlled by the lens control circuit 136.

The position of the XY stage 105 is controlled by the drive of each axis motor (not shown) which is controlled by the stage control mechanism 138. Based on the principle of laser interferometry, the stage position measurement instrument 139 measures the position of the XY stage 105 by receiving a reflected light from the mirror 210.

In the control computer 110, there are arranged a rasterization processing unit 50, a dose calculation unit 52, an irradiation time calculation unit 54, a group assignment processing unit 56, an allocation unit 58, a data processing unit 70, a writing control unit 72, and a transmission processing unit 74. Each of the “. . . units” such as the rasterization processing unit 50, the dose calculation unit 52, the irradiation time calculation unit 54, the group assignment processing unit 56, the allocation unit 58, the data processing unit 70, the writing control unit 72, and the transmission processing unit 74 includes processing circuitry. The processing circuitry includes, for example, an electric circuit, computer, processor, circuit board, quantum circuit, semiconductor device, or the like. Each “. . . unit” may use common processing circuitry (the same processing circuitry), or different processing circuitry (separate processing circuitry). Information input/output to/from the rasterization processing unit 50, the dose calculation unit 52, the irradiation time calculation unit 54, the group assignment processing unit 56, the allocation unit 58, the data processing unit 70, the writing control unit 72, and the transmission processing unit 74, and information being operated are stored in the memory 112 each time.

Writing operations of the writing apparatus 100 are controlled by the writing control unit 72. Processing of transmitting irradiation time data of each shot to the deflection control circuit 130 is controlled by the transmission processing unit 74.

Writing data (chip data) is input from the outside of the writing apparatus 100, and stored in the storage device 140. Chip data defines information on a plurality of figure patterns configuring a chip pattern. Specifically, for each figure pattern, each vertex coordinate is defined in order of forming a figure. Alternatively, for each figure pattern, a figure code, coordinates, a size, and the like are defined, for example.

FIG. 1 shows a configuration necessary for describing the first embodiment. Other configuration elements generally necessary for the writing apparatus 100 may also be included therein.

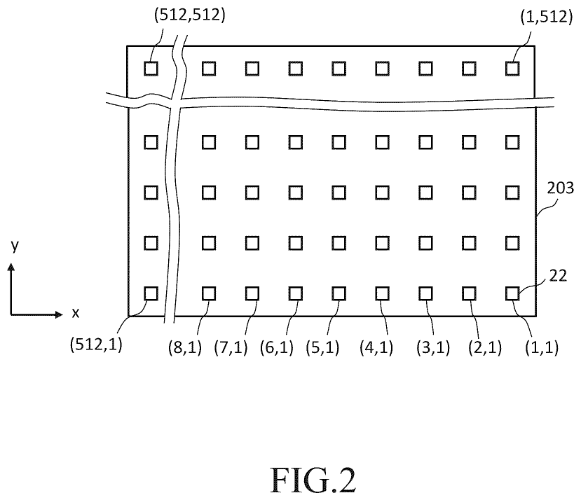

FIG. 2 is a conceptual diagram showing a configuration of a shaping aperture array substrate according to the first embodiment. As shown in FIG. 2, holes (openings) 22 of p columns wide (width in the x direction) and q rows long (length in the y direction) (p≥2, q≥2) are formed, like a matrix, at a predetermined array pitch in the shaping aperture array substrate 203. In the case of FIG. 2, for example, holes 22 of 512×512, that is 512 holes in the x direction and 512 holes in the y direction, are formed. The number of the holes 22 is not limited thereto. For example, it is also preferable to form the holes 22 of 32×32. Each of the holes 22 is a rectangle (including a square) having the same dimension and shape as each other. Alternatively, each of the holes 22 may be a circle with the same diameter as each other. Multiple electron beams 20 are formed by letting portions of an electron beam 200 individually pass through a corresponding one of a plurality of holes 22. In other words, the shaping aperture array substrate 203 forms and emits the multiple electron beams 20. The shaping aperture array substrate 203 serves as an example of an emission source of the multiple electron beams 20 or an example of a multiple beam forming mechanism.

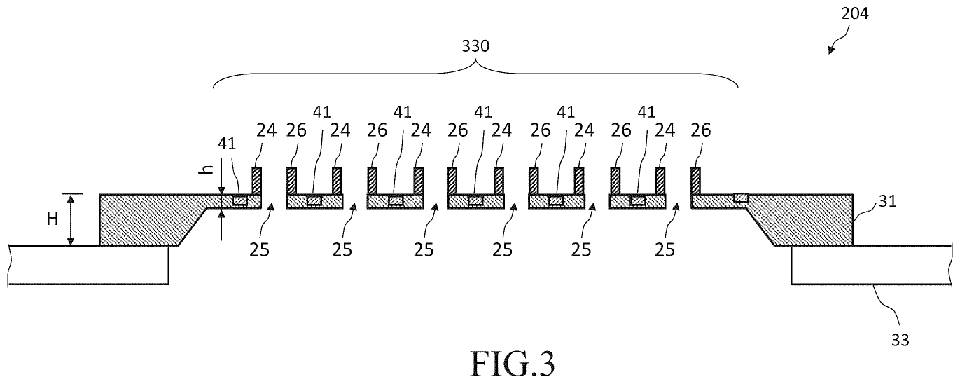

FIG. 3 is a sectional view showing a configuration of a blanking aperture array mechanism according to the first embodiment. In the blanking aperture array mechanism 204, as shown in FIG. 3, a blanking aperture array substrate 31 being a semiconductor substrate made of silicon, etc. is disposed on a support table 33. In a membrane region 330 at the center of the blanking aperture array substrate 31, a plurality of passage holes 25 (openings), through each of which a corresponding one of the multiple electron beams 20 passes, are formed at positions each corresponding to each hole 22 in the shaping aperture array substrate 203 shown in FIG. 2. A pair of a control electrode 24 and a counter electrode 26, (blanker: blanking deflector), is arranged in a manner such that the electrodes 24 and 26 are opposite to each other across a corresponding one of the plurality of the passage holes 25. A control circuit 41 (logic circuit) which applies a deflection voltage to the control electrode 24 for the passage hole 25 concerned is disposed, inside the blanking aperture array substrate 31, close to each corresponding passage hole 25. The counter electrode 26 for each beam is grounded.

In the control circuit 41, an amplifier (not shown) (an example of a switching circuit) is arranged. As an example of the amplifier, a CMOS (Complementary MOS) inverter circuit serving as a switching circuit is disposed. With regard to inputs (IN) to the CMOS inverter circuit, either an L (low) potential (e.g., ground potential) lower than a threshold voltage, or an H (high) potential (e.g., 1.5 V) higher than or equal to the threshold voltage is applied as a control signal. According to the first embodiment, in a state where an L potential is applied to the input (IN) of the CMOS inverter circuit, the output (OUT) of the CMOS inverter circuit, which is to be output from the control circuit 41, becomes a positive potential (Vdd), and then, a corresponding beam is deflected by an electric field due to a potential difference from the ground potential of the counter electrode 26, and is controlled to be in a beam-OFF condition by being blocked by the limiting aperture substrate 206. In contrast, in a state (active state) where an H potential is applied to the input (IN) of the CMOS inverter circuit, the output (OUT) of the CMOS inverter circuit, which is to be output from the control circuit 41, becomes a ground potential, and therefore, since there is no potential difference from the ground potential of the counter electrode 26, a corresponding beam is not deflected, and is controlled to be in a beam-ON condition by passing through the limiting aperture substrate 206. Blanking control is provided by such deflection.

Next, operations of the writing mechanism 150 is described. The electron beam 200 emitted from the electron gun 201 (emission source) almost perpendicularly (for example, vertically) illuminates the whole of the shaping aperture array substrate 203 by the illumination lens 202. A plurality of rectangular holes 22 (openings) are formed in the shaping aperture array substrate 203. The region including all of the plurality of holes 22 is irradiated with the electron beam 200. For example, rectangular multiple beams (a plurality of electron beams) 20 are formed by letting portions of the electron beam 200 applied to the positions of the plurality of holes 22 individually pass through a corresponding one of the plurality of holes 22 in the shaping aperture array substrate 203. The multiple electron beams 20 individually pass through corresponding blankers of the blanking aperture array mechanism 204. The blanker provides blanking control such that a corresponding beam individually passing becomes in an ON condition during the set writing time (irradiation time).

The multiple electron beams 20 having passed through the blanking aperture array mechanism 204 are reduced by the reducing lens 205, and travel toward the hole in the center of the limiting aperture substrate 206. The electron beam which was deflected by the blanker of the blanking aperture array mechanism 204 deviates from the hole in the center of the limiting aperture substrate 206 and is blocked by the limiting aperture substrate 206. In contrast, the electron beam which was not deflected by the blanker of the blanking aperture array mechanism 204 passes through the hole in the center of the limiting aperture substrate 206 as shown in FIG. 1. Thus, the limiting aperture substrate 206 blocks each beam which was deflected to be in an OFF state by the blanker of the blanking aperture array mechanism 204. Then, each beam for one shot of the multiple electron beams 20 is formed by a beam which has been made during a period from becoming beam-ON to becoming beam-OFF and has passed through the limiting aperture substrate 206. The multiple electron beams 20 having passed through the limiting aperture substrate 206 are focused by the objective lens 207 so as to be a pattern image of a desired reduction ratio. Then, all of the multiple electron beams 20 having passed through the limiting aperture substrate 206 are collectively deflected in the same direction by the main deflector 208 and the sub deflector 209 in order to irradiate respective beam irradiation positions on the target object 101. For example, when the XY stage 105 is continuously moving, tracking control is performed by the main deflector 208 so that the beam irradiation position may follow the movement of the XY stage 105. Ideally, the multiple electron beams 20 irradiating at a time are aligned at a pitch obtained by multiplying the array pitch of a plurality of holes 22 in the shaping aperture array substrate 203 by the desired reduction ratio described above.

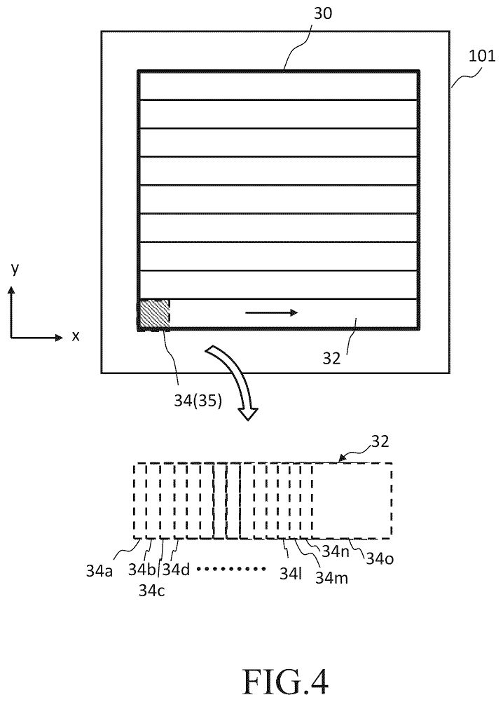

FIG. 4 is a conceptual diagram for explaining an example of a writing operation according to the first embodiment. As shown in FIG. 4, a writing region 30 (bold line) of the target object 101 is virtually divided into a plurality of stripe regions 32 by a predetermined width in the y direction, for example. In the case of FIG. 4, the writing region 30 of the target object 101 is divided in the y direction, for example, into a plurality of stripe regions 32 by the width size being substantially the same as the design size of an irradiation region 34 (writing field) that can be irradiated with one irradiation of the multiple electron beams 20. The x-direction design size of the irradiation region 34 of the multiple electron beams 20 can be defined by (the number of x-direction beams)×(x-direction beam pitch). The y-direction size of the rectangular irradiation region 34 can be defined by (the number of y-direction beams)×(y-direction beam pitch).

First, the XY stage 105 is moved to make an adjustment such that the irradiation region 34 of the multiple electron beams 20 is located at the left end, or at a position further left than the left end, of the first stripe region 32, and then, writing of the first stripe region 32 is performed. When writing the first stripe region 32, the XY stage 105 is moved, for example, in the −x direction, so that the writing may proceed relatively in the x direction. The XY stage 105 is moved, for example, continuously at a constant speed. After writing the first stripe region 32, the stage position is moved in the −y direction by the width of the stripe region 32.

Next, an adjustment is made so that the irradiation region 34 of the multiple electron beams 20 can be located at the left end, or at a position further left than the left end, of the second stripe region 32. Then, writing of the second stripe region 32 is performed by moving the XY stage 105, for example, in the −x direction to proceed the writing relatively in the x direction.

In the example described above, respective stripe regions 32 are written in the same direction, but, it is not limited thereto. For example, with respect to the stripe region 32 to be written following the stripe region 32 having been written in the x direction, it may be written in the −x direction by moving the XY stage 105 in the x direction, for example. Thus, due to performing writing while alternately changing the writing direction, the stage moving time can be reduced, which results in reducing the writing time. Owing to one shot of multiple electron beams 20 having been formed by individually passing through the holes 22 in the shaping aperture array substrate 203, a plurality of shot patterns up to the number of the holes 22 are maximally formed at a time.

Although FIG. 4 shows the case where the stage moving for writing each stripe region is performed once for each writing, it is not limited thereto. It is also preferable to perform multiple writing (multiple pass writing) such that the stage moves on the same position a plurality of times. In that case, preferably, the multiple writing is performed while shifting the position in the y direction by 1/n of the width of the stripe region, for example. Alternatively, it is also preferable to perform multiple writing (multiple writing in a pass) that writes the same position plural times by different beams during one stage movement.

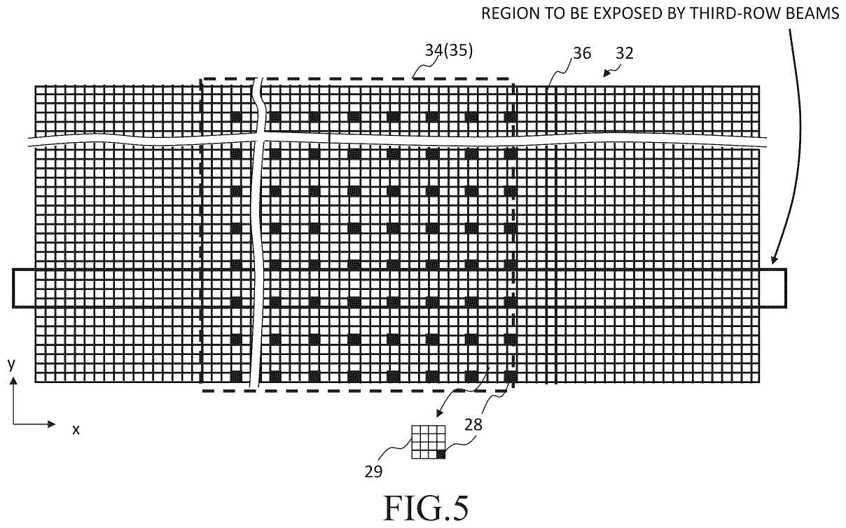

FIG. 5 is an illustration showing an example of an irradiation region of multiple electron beams and a pixel to be written (writing target pixel) according to the first embodiment. In FIG. 5, the stripe region 32 is divided into a plurality of mesh regions by the beam size of each of the multiple electron beams 20, for example. Each mesh region serves as a writing target pixel 36 (irradiation unit region, irradiation position). The pixel 36 is also referred to as an irradiation unit region. The size of the writing target pixel 36 is not limited to the beam size, and may be any size regardless of beam size. For example, it may be 1/n (n being an integer of 1 or more) of the beam size. FIG. 5 shows the case where the writing region on the target object 101 is divided, for example, in the y direction, into a plurality of stripe regions 32 by the width size being substantially the same as the size of the irradiation region 34 (writing field) that can be irradiated with one irradiation of the multiple electron beams 20. The x-direction size of the rectangular, including square, irradiation region 34 can be defined by (the number of x-direction beams)×(x-direction beam pitch). The y-direction size of the rectangular irradiation region 34 can be defined by (the number of y-direction beams)×(y-direction beam pitch). FIG. 5 shows the case of multiple beams of 512×512 (rows×columns) having been simplified to 8×8 (rows ×columns). In the irradiation region 34, there are shown a plurality of pixels 28 (beam writing positions) which can be irradiated with one shot of the multiple electron beams 20. The pitch between adjacent pixels 28 is the beam pitch (pitch between beams) of the multiple beams. A sub-irradiation region 29 (pitch cell region) is configured by a rectangular, including square, region surrounded by the size of beam pitches in the x and y directions. In the example of FIG. 5, each sub-irradiation region 29 is composed of 4×4 pixels, for example.

In the writing apparatus using multiple electron beams, since different pixels are exposed with multiple beams at a time, high-speed writing can be performed using a large beam current. Furthermore, because of miniaturization of patterns, the mask process has been shifted to a low sensitivity resist. For exposing a low sensitivity resist, a higher dose is needed, and therefore, it is important to enhance the total beam current by increasing a current density and the number of beams. However, in the multiple electron beam writing, if the total beam current becomes large, beam blur occurs due to the Coulomb effect, which degrades the resolution performance.

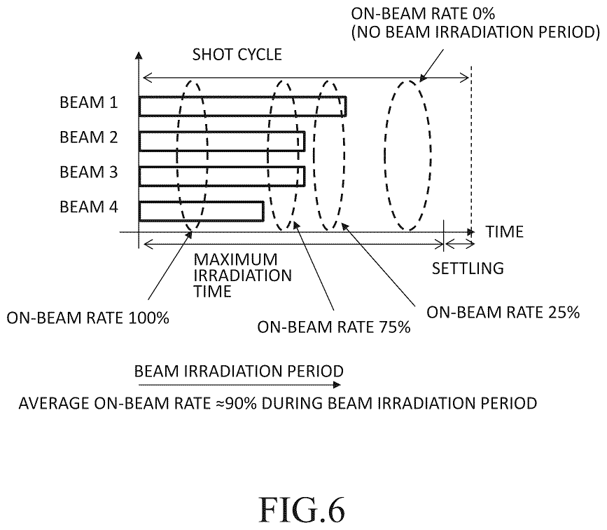

FIG. 6 is an illustration showing an example of an irradiation time of one shot of multiple electron beams according to a comparative example of the first embodiment. In the comparative example, the multiple electron beams 20 are applied based on a counter system which controls the irradiation time of each beam. Specifically, the irradiation start timing of the multiple electron beams 20 is set to be simultaneous, and each irradiation is performed based on an irradiation time which is individually set for the pixel 36 to be irradiated with respective beams. Then, when the irradiation time has passed, beam irradiation is stopped. In other words, all the beams become ON simultaneously, and each beam becomes OFF individually.

The irradiation time in multiple electron beam writing is calculated as a value obtained by multiplying a coverage rate (pattern area density) of the pixel 36 by a correction dose such as a proximity effect correction dose. In many cases, a shot cycle (fixed) is set based on the case where the irradiation time of the pixel 36, when the pattern area density is 100% and a correction dose is maximum (e.g., proximity effect density 0), is defined as the maximum irradiation time per shot.

Therefore, at the time of irradiation start, the ON-beam rate is about 100%, and this state continues. Then, with the time passes, the ON-beam rate decrease, and in spite of during a shot cycle, in many cases, the ON-beam rate becomes 0% in the last period. The ON-beam rate indicates the rate of the number of ON beams to the total number of the multiple electron beams 20. Therefore, the average ON-beam rate during beam irradiation from beam irradiation starting to the time of the last beam becoming beam-OFF increases to about 90%, for example, in the case of FIG. 6. Thus, since beam-ON timings are unevenly distributed in the former half of the shot cycle, the total beam current during beam irradiation becomes high. Therefore, in the comparative example, there is a problem that since beam blur occurs due to the Coulomb effect, the resolution performance is degraded. Thus, it is desirable to reduce the average ON-beam current during beam irradiation by reducing the number of beams becoming simultaneously ON.

According to the first embodiment, a pixel-set (an example of an irradiation-unit-region-set) of a plurality of pixel-sets is formed to be composed of a target pixel concerned and another pixel for each pixel. Then, in the same pixel-set, at least a partial dose is allocated from one to the other in order to reduce the number of beams becoming simultaneously ON in each shot. It will be described in detail.

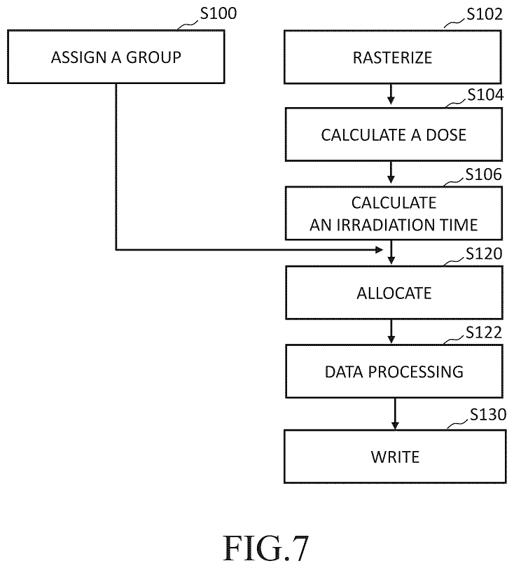

FIG. 7 is a flowchart showing an example of main steps of a writing method according to the first embodiment. In FIG. 7, the writing method of the first embodiment executes a series of steps: a group assignment step (S100), a rasterization processing step (S102), a dose calculation step (S104), an irradiation time calculation step (S106), an allocation step (S120), a data processing step (S122), and a writing step (S130).

In the group assignment step (S100), the group assignment processing unit 56 assigns one of a plurality of groups to each of a plurality of pixels 36 (irradiation unit regions), which are unit regions to be irradiated with each beam of the multiple electron beams 20, obtained by dividing the stripe region 32 (an example of a writing region) of the target object 101, in such a manner that the pixels 36 which are in advance set to form the same pixel-set of the plurality of pixel-sets belong to different groups, and that pixels 36 to be irradiated with each shot of the multiple electron beams 20 include pixels 36 of different groups.

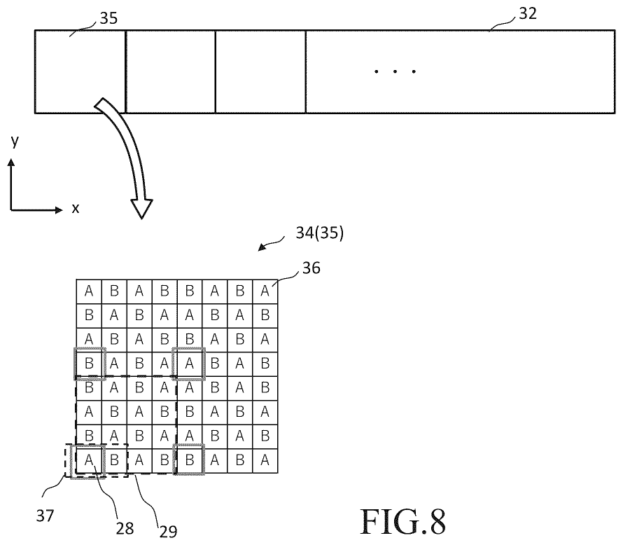

FIG. 8 is an illustration showing an example of assigning a group to a pixel according to the first embodiment. In FIG. 8, first, each stripe region 32 of the target object 101 is divided into a plurality of rectangular regions 35 of the same size as the irradiation region 34 of the multiple electron beams 20. FIG. 8 shows the case of 2×2 multiple electron beams 20, for example, and four pixels 36 are arranged in a pitch between beams, for example. In that case, the rectangular region 35 being the same size as the irradiation region 34 is composed of 8×8 pixels, for example.

FIG. 8 shows the case where each pixel-set is composed of adjacent pixels. Specifically, one pixel-set is composed of two pixels adjacent to each other in the x direction in the same sub-irradiation region 29 (beam pitch region).

For example, as shown in the example of FIG. 8, with respect to the sub-irradiation region 29 composed of 4×4 pixels, the first pixel from the left in the first row from the bottom and the second pixel from the left in the first row from the bottom form one pixel-set. Furthermore, the third pixel from the left in the first row from the bottom and the fourth pixel from the left in the first row from the bottom form another pixel-set. Furthermore, the first pixel from the left in the second row from the bottom and the second pixel from the left in the second row from the bottom form another pixel-set. Furthermore, the third pixel from the left in the second row from the bottom and the fourth pixel from the left in the second row from the bottom form another pixel-set. After this, similarly, pixel-sets are formed in each of the rows aligned in the y direction.

Alternatively, for example, as shown in the example of FIG. 8, with respect to the sub-irradiation region 29 composed of 4×4 pixels, the first pixel from the left in the first row from the bottom and the first pixel from the left in the second row from the bottom form one pixel-set. Furthermore, the first pixel from the left in the third row from the bottom and the first pixel from the left in the fourth row from the bottom form another pixel-set. Furthermore, the second pixel from the left in the first row from the bottom and the second pixel from the left in the second row from the bottom form another pixel-set. Furthermore, the second pixel from the left in the third row from the bottom and the second pixel from the left in the fourth row from the bottom form another pixel-set. After this, similarly, pixel-sets are formed in each of the columns aligned in the x direction.

Then, one of a plurality of groups A and B being different from each other is individually assigned to adjacent pixels 36 in each pixel-set such that each of the adjacent pixels 36 belongs to a different group. In that case, the plurality of groups are assigned to be alternate each other in both the x and y directions.

Group assignment is performed such that a plurality of pixels 28 to be irradiated with each shot of the multiple electron beams 20 include pixels of different groups. FIG. 8 shows the case where group assignment is performed such that beams adjacent in the x and y directions of 2×2 multiple electron beams 20 irradiate the pixels 28 of different groups.

When four pixels are arranged in a pitch between beams, although pixels of the same group are aligned at the border of the sub-irradiation regions 29, it is acceptable because those pixels belong to different pixel-sets.

In the rasterization processing step (S102), the rasterization processing unit 50 reads chip pattern data (writing data) from the storage device 140, and performs rasterization processing. Specifically, for each pixel 36, a pattern density ρ(x) (pattern area density) of a figure pattern arranged in the pixel concerned is calculated. For example, it is preferable to perform rasterization processing for each stripe region 32.

In the dose calculation step (S104), the dose calculation unit 52 calculates, for each pixel 36, a dose (irradiation amount) to be incident on the pixel 36 concerned. Specifically, it operates as follows: For example, the dose D can be calculated by multiplying a preset base dose D_{base}, a proximity effect correction dose Dₚ, and a pattern density ρ. The proximity effect correction dose Dₚ is obtained as a relative value standardized by defining the base dose D_{base} to be 1. Thus, it is preferable to obtain the dose D to be in proportion to a pattern area density calculated for each pixel 36. With respect to the proximity effect correction dose Dₚ, the writing region (for example, in this case, the stripe region 32) is virtually divided into a plurality of proximity mesh regions (mesh regions for proximity effect correction calculation) by a predetermined size. The size of the proximity mesh region is preferably set to be about 1/10 of the influence range of the proximity effect, such as about 1 μm. Then, writing data is read from the storage device 140, and, for each proximity mesh region, a pattern density ρ′ (pattern area density) of a pattern arranged in the proximity mesh region concerned is calculated.

Next, a proximity effect correction dose Dₚ for correcting a proximity effect is calculated for each proximity mesh region. Here, the size of the mesh region to calculate the proximity effect correction dose Dₚ does not need to be the same as the size of the mesh region to calculate a pattern density ρ. Furthermore, a correction model of the proximity effect correction dose Dₚ and its calculation method may be the same as those used in the conventional single beam writing system. A dose map which defines dose data for each pixel 36 is generated.

In the case of performing multiple writing, a dose map is generated for each writing processing of each time of multiple writing. In other words, a dose map is generated for each stripe layer. The generated dose map is stored in the storage device 142.

In the irradiation time calculation step (S106), the irradiation time calculation unit 54 calculates, for each pixel 36, the irradiation time “t” of an electron beam for applying a calculated dose D to the pixel 36 concerned. The irradiation time “t” can be obtained by dividing the dose D by the current density J. Thereby, an irradiation time map defining irradiation time data for each pixel 36 is generated. The generated irradiation time map is stored in the storage device 142.

In the allocation step (S120), the allocation unit 58 performs allocation, with respect to each pixel-set, in order that the irradiation time of the pixel 36 to which the group A of a plurality of groups A and B has been assigned can be longer than the irradiation time of the pixel 36, in the same pixel-set, to which another group, the group B, has been assigned, in such a manner that at least a part of the irradiation time of the pixel 36 to which the another group, the group B, has been assigned is allocated to the irradiation time of the pixel 36 to which the group A has been assigned.

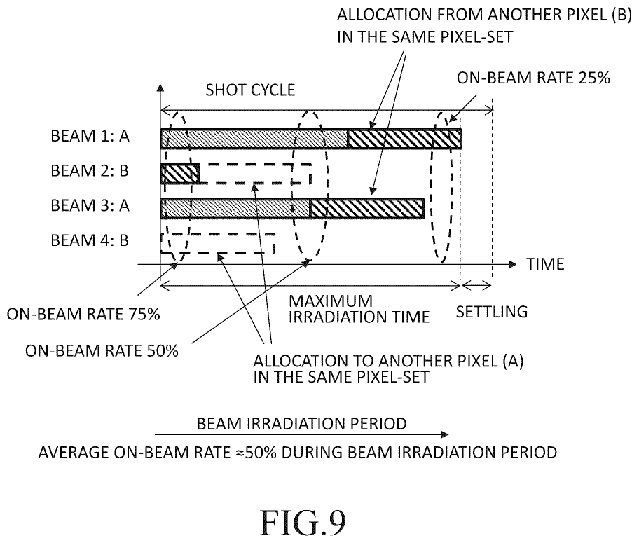

FIG. 9 is an illustration showing an example of an irradiation time of one shot of multiple electron beams according to the first embodiment. In the first embodiment, the multiple electron beams 20 are applied based on a counter system which controls the irradiation time of each beam. FIG. 9 shows the case of using 2×2 multiple electron beams 20 of beams 1 to 4. In the example of FIG. 9, a certain shot applies beams 1 and 3, located diagonally, to the pixels of the group A, and beams 2 and 4, located diagonally, to the pixels of the group B. It is preferable to allocate an irradiation time as much as possible to the pixel of the group A from the pixel of the group B in the same pixel-set so that the irradiation time of the pixel of the group A can be as close as possible to the preset maximum irradiation time.

With respect to the pixel of the group A to be irradiated with the beam 1, at least a part of the irradiation time of the pixel of the group B in the same pixel-set is allocated. FIG. 9 shows the case where the irradiation time of the pixel of the group A has reached the maximum irradiation time by being allocated with the irradiation time of the pixel of the group B in the same pixel-set. If there is an irradiation time which is not needed to be further allocated because the irradiation time of the pixel in the group A has reached the maximum, this irradiation time is set to the pixel of the group B in the same pixel-set.

With respect to the pixel of the group B to be irradiated with the beam 2, its at least partial irradiation time is allocated to the pixel of the group A in the same pixel-set. In the case of FIG. 9, since the irradiation time of the pixel of the group A has reached the maximum irradiation time due to that allocation, a remaining irradiation time which is not needed to be further allocated to the group A is set to the pixel of the group B in the same pixel-set.

With respect to the pixel of the group A to be irradiated with the beam 3, at least a part of the irradiation time of the pixel of the group B in the same pixel-set is allocated. FIG. 9 shows the case where the irradiation time of the pixel of the group A has not reached the maximum irradiation time although all the irradiation time defined for the pixel of the group B in the same pixel-set has been allocated to the pixel of the group A. Therefore, the irradiation time of the pixel of the group B in the same pixel-set is set to be zero.

With respect to the pixel of the group B to be irradiated with the beam 4, its at least partial irradiation time is allocated to the pixel of the group A in the same pixel-set. FIG. 9 shows the case where since the irradiation time of the pixel of the group A has not reached the maximum irradiation time or has just reached the maximum irradiation time, the irradiation time of the pixel of the group B becomes zero. The irradiation time after the allocation is set to the pixel of the group A in the same pixel-set.

As described above, because the irradiation time is allocated to the pixel of the group A from the pixel of the group B, it is possible to make the ON-beam rate less than 100% from the time of starting the irradiation, and when some time passes, to make it decrease to 50%, for example. Therefore, the average ON-beam rate during the beam irradiation from starting beam irradiation until the last beam becomes beam OFF can be decreased, and, for example, in the case of FIG. 9, it is decreased to about 50%. Thus, since the number of ON-beams can be reduced throughout the shot cycle, the entire beam current during beam irradiation can be decreased. Therefore, according to the first embodiment, it is possible to prevent or reduce a beam blur occurring due to the Coulomb effect, and prevent or reduce a resolution deterioration.

Now, the irradiation time t_{A}′, after allocation, of the pixel of the group A, and the irradiation time t_{B}′, after allocation, of the pixel of the group B in the same pixel-set can be defined as follows using the irradiation time t_{A} of the pixel of the group A, the irradiation time t_{B} of the pixel of the group B in the same pixel-set, and the maximum irradiation time tₘₐₓ. The irradiation time Δ to be added to the pixel of the group A can be defined by the following equation (1).

Δ=tₘₐₓ−t_{A} (1)

If the irradiation time Δ>t_{B}, the equation (2) below can define the irradiation time t_{A}′ and the irradiation time t_{B}′.

t_{A}′=t_{A}+t_{B}, t_{B}′=0 (2)

If the irradiation time Δ<t_{B}, the equation (3) below can define the irradiation time t_{A}′ and the irradiation time t_{B}′.

t_{A}′=t_{A}+Δ, t_{B}′=t_{B}−Δ (3)

Alternatively, the irradiation time may be allocated by using a beam current i of each beam. It will be described in detail.

The dose d (=DA, where D indicates a dose per unit area, and A indicates a pixel area) with which the pixel 36 is irradiated can be defined by the product of the beam current amount i (=JA) and the irradiation time t. Then, using a beam current i_{A} of the beam of the group A, and a beam current i_{B} of the beam of the group B, the irradiation time t_{A}′, after allocation, of the pixel of the group A, and the irradiation time t_{B}′, after allocation, of the pixel of the group B in the same pixel-set can be defined as follows: The irradiation time Δ to be added to the pixel of the group A is the same as the equation (1).

If the irradiation time Δ·i_{A}>t_{B}·i_{B}, the equation (4) below can define the irradiation time t_{A}′ and the irradiation time t_{B}′.

t_{A}′=t_{A}+(i_{B}/i_{A})t_{B}, t_{B}′=0 (4)

If the irradiation time Δ·i_{A}<t_{B}·i_{B}, the equation (5) below can define the irradiation time t_{A}′ and the irradiation time t_{B}′.

t_{A}′=t_{A}+Δ, t_{B}′=t_{B}−(i_{A}/i_{B})Δ (5)

In the above examples, the irradiation time is used as a target for allocation, but, it is not limited thereto. The dose may be used instead of the irradiation time. In that case, some or all of the dose of the pixel of the group B is allocated to the pixel of the group A. In that case, the allocation needs to be performed not to exceed the maximum dose dₗᵢₘ corresponding to the maximum irradiation time.

The dose d_{A}′, after allocation, of the pixel of the group A, and the dose d_{B}′, after allocation, of the pixel of the group B in the same pixel-set can be defined as follows using the dose d_{A}, per unit area, of the pixel of the group A, the dose d_{B}, per unit area, of the pixel of the group B in the same pixel-set, and the maximum dose dₗᵢₘ per unit area. The equation (6) below can define the dose Δ′ to be added to the pixel of the group A.

Δ=dₗᵢₘ−d_{A} (6)

If the dose Δ′>d_{B}, the equation (7) below can define the dose d_{A}′ and the dose d_{B}′.

d_{A}′=d_{A}+d_{B}, d_{B}′=0 (7)

If the dose Δ′<d_{B}, the equation (8) below can define the dose d_{A}′ and the dose d_{B}′.

d_{A}′=d_{A}+Δ′, d_{B}′=d_{B}−Δ′ (8)

When a dose is used as a target for allocation instead of an irradiation time, the allocation step (S120) is performed between the dose calculation step (S104) and the irradiation time calculation step (S106). Then, in the irradiation time calculation step (S106), the irradiation time after allocation is calculated as described below by the irradiation time calculation unit 54.

The irradiation time t_{A}′ after allocation and the irradiation time t_{B}′ after allocation can be defined by the equation (9) below.

t_{A}′=d_{A}′/i_{A}, t_{B}′=d_{B}′/i_{B} (9)

As described above, allocation is performed, with respect to each pixel-set, in order that the dose or the irradiation time of the pixel 36 to which the group A has been assigned may become larger or longer than the dose or the irradiation time of the pixel 36, in the same pixel-set, to which the group B has been assigned, in such a manner that at least a part of the dose or the irradiation time of the pixel 36 to which the group B has been assigned is allocated to the pixel 36 to which the group A has been assigned. FIG. 9 shows the case where a preset maximum dose or a preset maximum irradiation time is set to the pixel 36, to which the group A has been assigned, to be irradiated with the beam 1.

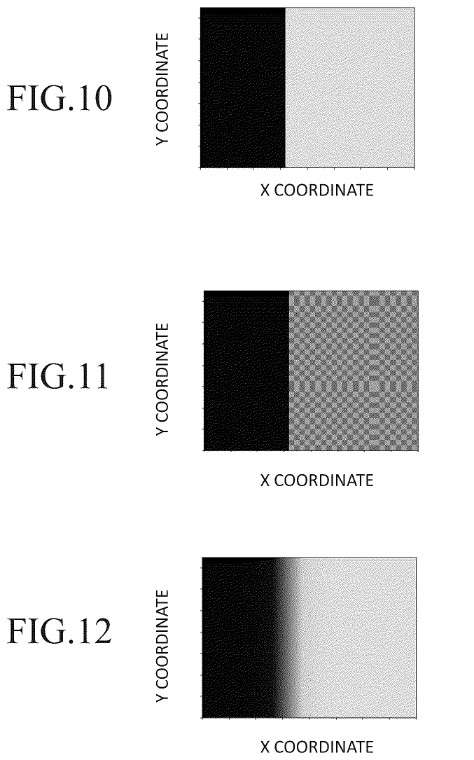

FIG. 10 is an illustration showing an example of a dose distribution before allocation according to the first embodiment.

FIG. 11 is an illustration showing an example of a dose distribution after allocation according to the first embodiment.

FIG. 12 is an illustration showing an example of an accumulated dose distribution to the resist after allocation according to the first embodiment.

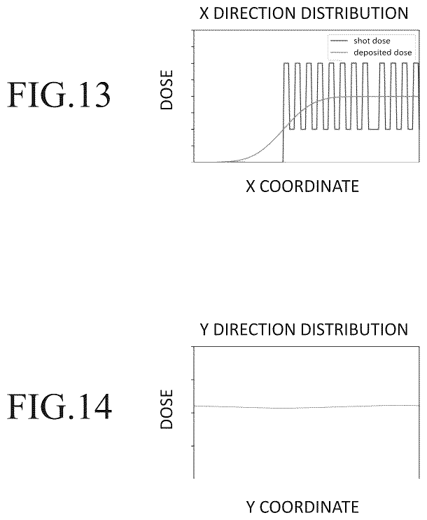

FIG. 13 is an illustration showing an example of a dose distribution in the x direction after allocation according to the first embodiment.

FIG. 14 is an illustration showing an example of a dose distribution in the y direction after allocation according to the first embodiment.

FIGS. 10 to 14 show the cases of using 2×2 multiple electron beams 20 of the beams 1 to 4. Here, 20 nm blur is set as a synthesis of a beam blur and a resist blur. Furthermore, FIGS. 10 to 14 show the cases where the irradiation time based on which the dose before allocation of each of the beams 1 to 4 is 1.0 (value standardized by defining the reference dose to be 1), and based on which the dose after allocation of each of the beams 1 and 3 of the group A is 1.5, and the dose after allocation of each of the beams 2 and 4 of the group B is 0.5. As shown in FIG. 10, in the dose distribution before allocation, the dose of each pixel in the portion where a pattern exits is constant at 1.0. In contrast, as shown in FIGS. 11 and 13, by setting pixels adjacent to each other in the x direction as one pixel-set, and allocating a half (dose of 0.5) of the irradiation time to the pixel of the group A from the pixel of the group B, the irradiation time changes alternately with respect to each pixel, and the dose distribution becomes hound's tooth. As shown in FIG. 12, when performing writing based on that dose distribution after allocation, the accumulated dose to the resist of the surface of the target object 101 can be almost constant. As shown in FIG. 13, the accumulated dose distribution in the x direction becomes uniform inside the pattern after it increases at the pattern edge. As shown in FIG. 14, the accumulated dose distribution in the y direction is uniform along the pattern edge.

According to the first embodiment, a blur (resist blur, beam blur) larger than the distance between pixels is used. A dose difference occurring from an irradiation time difference between the groups A and B in each pixel-set can be equalized by an averaging effect in space such as overlapping of doses of adjacent beams due to a large blur (resist blur, beam blur) larger than the distance between pixels. As a result, a dose difference (large or small) of pixels between the groups in each pixel-set can be eliminated.

In the data processing step (S122), the data processing unit 70 performs data processing to rearrange the irradiation time data in the order of shots. The irradiation time data is stored in the storage device 142.

Then, the transmission processing unit 74 transmits the irradiation time data to the deflection control circuit 130 in the order of shots.

In the writing step (S130), under the control of the writing control unit 72, the writing mechanism 150 writes a pattern to the target object 101 with the multiple electron beams 20 such that a plurality of pixels 36 are irradiated with electron beams whose each dose or irradiation time is defined based on allocation of a dose or an irradiation time.

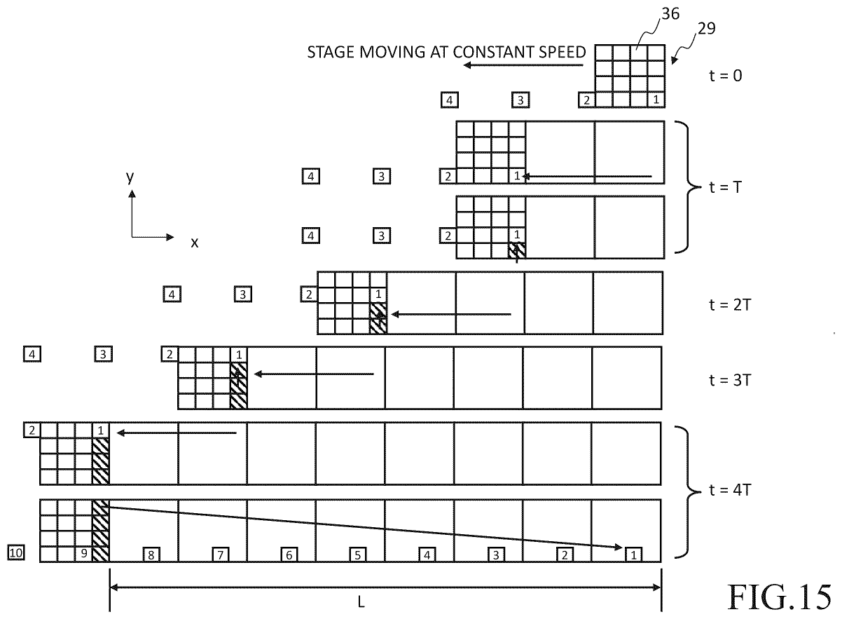

FIG. 15 is an illustration for explaining an example of a multi-beam writing operation according to the first embodiment. FIG. 15 shows the case where the inside of each sub-irradiation region 29 is written with four different beams. Furthermore, the example of FIG. 6 shows a writing operation where, during a ¼ region namely the region of 1/(the number of beams used for irradiation) in each sub-irradiation region 29 being written, the XY stage 105 continuously moves at the speed at which it moves the distance L of eight beam pitches. In the writing operation shown in FIG. 15, for example, while the XY stage 105 moves the distance L of eight beam pitches, four different pixels in the same sub-irradiation region 29 are written (exposed) by applying four shots of the multiple beams 20 at a shot cycle T with shifting the irradiation position (pixel 36) in order by the sub deflector 209. In order that the relative position between the irradiation region 34 and the target object 101 may not be shifted by the movement of the XY stage 105 while these four pixels 36 are written (exposed), the irradiation region 34 is made to follow the movement of the XY stage 105 by collective deflection of all of the multiple beams 20 by the main deflector 208. In other words, a tracking control is performed. After one tracking cycle is completed, tracking is reset to return to the previous (last) tracking start position. Since writing of the pixels in the first column from the right of each sub-irradiation region 29 has been completed, in the next tracking cycle after resetting the tracking, first, the sub deflector 209 provides deflection such that the beam writing position is adjusted (shifted) to write the second pixel column from the right still not having been written in each sub-irradiation region 29, for example. By repeating this operation during performing writing to the stripe region 32, as shown in the lower part of FIG. 4, the position of the irradiation region 34 of the multiple beams 20 is sequentially moved (shifted), such as the irradiation region from 34a, 34b, 34c, . . . to 34o, to perform writing.

As described above, according to the first embodiment, the average ON-beam current during beam irradiation in each shot cycle can be reduced.

### Second Embodiment

In the first embodiment described above, one of two groups A and B is assigned to each of a plurality of pixels, but it is not limited thereto. According to a second embodiment, one of three or more groups is assigned to each of a plurality of pixels. An example of the configuration of the writing apparatus in the second embodiment is the same as that of FIG. 1. The flowchart showing an example of main steps of a writing method according to the second embodiment is the same as that of FIG. 7. The contents of the second embodiment are the same as those of the first embodiment except for what is particularly described below.

In the group assignment step (S100), the group assignment processing unit 56 assigns one of a plurality of groups A, B, C, and D to each of a plurality of pixels 36 (irradiation unit regions), which are unit regions to be irradiated with each beam of the multiple electron beams 20, obtained by dividing the stripe region 32 (an example of a writing region) of the target object 101, in such a manner that the pixels 36 which are in advance set to form the same pixel-set belong to different groups, and that a plurality of pixels 36 to be irradiated with each shot of the multiple electron beams 20 include pixels 36 of different groups.

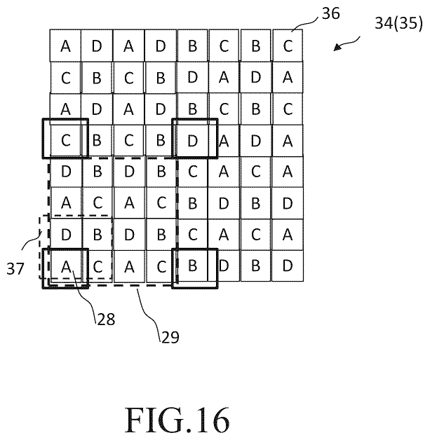

FIG. 16 is an illustration showing an example of assignment of groups to pixels according to the second embodiment. In the example of FIG. 16, one of the four groups A, B, C, and D is assigned to each pixel 36. In each sub-irradiation region 29, each one of the group A, B, C, and D is assigned each 2×2 adjacent pixels 36. Each 2×2 adjacent pixels 36 (groups A, B, C, and D) forms one pixel-set 37.

Group assignment is performed such that a plurality of pixels 28 to be irradiated with each shot of the multiple electron beams 20 include pixels of different groups. Therefore, with respect to 2×2 sub-irradiation regions 29, if the pixel 28 to be irradiated in the lower left sub-irradiation region 29 is the group A, group assignment is performed, for example, such that the pixel 28 to be irradiated in the lower right sub-irradiation region 29 is the group B, the pixel 28 to be irradiated in the upper left sub-irradiation region 29 is the group C, and the pixel 28 to be irradiated in the upper right sub-irradiation region 29 is the group D.

For example, in the lower left sub-irradiation region 29, with respect to each of four pixel-sets 37, the first pixel from the left in the first row from the bottom is the group A, the second pixel from the left in the first row from the bottom is the group C, the first pixel from the left in the second row from the bottom is the group D, and the second pixel from the left in the second row from the bottom is the group B.

For example, in the lower right sub-irradiation region 29, with respect to each of four pixel-sets 37, the first pixel from the left in the first row from the bottom is the group B, the second pixel from the left in the first row from the bottom is the group D, the first pixel from the left in the second row from the bottom is the group C, and the second pixel from the left in the second row from the bottom is the group A.

For example, in the upper left sub-irradiation region 29, with respect to each of four pixel-sets 37, the first pixel from the left in the first row from the bottom is the group C, the second pixel from the left in the first row from the bottom is the group B, the first pixel from the left in the second row from the bottom is the group A, and the second pixel from the left in the second row from the bottom is the group D.

For example, in the upper right sub-irradiation region 29, with respect to each of four pixel-sets 37, the first pixel from the left in the first row from the bottom is the group D, the second pixel from the left in the first row from the bottom is the group A, the first pixel from the left in the second row from the bottom is the group B, and the second pixel from the left in the second row from the bottom is the group C.

In the allocation step (S120), the allocation unit 58 performs allocation, with respect to each pixel-set, in order that the irradiation time of the pixel 36 to which the group A of a plurality of groups A, B, C, and D has been assigned can be longer than the irradiation time of each of the pixels 36, in the same pixel-set, to which the other groups B, C, or D have been individually assigned, in such a manner that at least a part of the irradiation time of the pixel 36 to which at least one of the other groups B, C, or D has been assigned is allocated to the irradiation time of the pixel 36 to which the group A has been assigned.

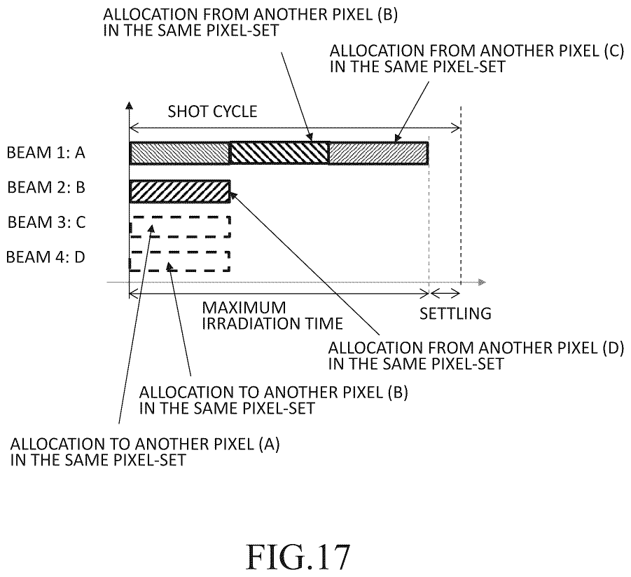

FIG. 17 is an illustration showing an example of an irradiation time of one shot of multiple electron beams according to the second embodiment. In the second embodiment, the multiple electron beams 20 are applied based on a counter system which controls the irradiation time of each beam. FIG. 17 shows the case of using 2×2 multiple electron beams 20 of beams 1 to 4. In the example of FIG. 17, in a certain shot, the beam 1 located lower left irradiates the pixel of the group A, the beam 2 located lower right irradiates the pixel of the group B, the beam 3 located upper left irradiates the pixel of the group C, and the beam 4 located upper right irradiates the pixel of the group D.

Specifically, an irradiation time as much as possible is allocated to the pixel of the group A of the first priority from the pixel of the group B in the same pixel-set so that the irradiation time of the pixel of the group A can be as close as possible to the preset maximum irradiation time. In the case of not reaching the maximum irradiation time, an irradiation time as much as possible is further allocated from the pixel of the group C in the same pixel-set so that the irradiation time of the pixel of the group A can be as close as possible to the preset maximum irradiation time. In the case of not yet reaching the maximum irradiation time, an irradiation time as much as possible is further allocated from the pixel of the group D in the same pixel-set so that the irradiation time of the pixel of the group A can be as close as possible to the preset maximum irradiation time.

Next, an irradiation time as much as possible is allocated to the pixel of the group B of the second priority from the pixel of the group C in the same pixel-set so that the irradiation time of the pixel of the group B can be as close as possible to the preset maximum irradiation time. In the case of not reaching the maximum irradiation time, an irradiation time as much as possible is further allocated from the pixel of the group D in the same pixel-set so that the irradiation time of the pixel of the group B can be as close as possible to the preset maximum irradiation time.

Next, an irradiation time as much as possible is allocated to the pixel of the group C of the third priority from the pixel of the group D in the same pixel-set so that the irradiation time of the pixel of the group C can be as close as possible to the preset maximum irradiation time.

If there is an irradiation time which is not needed to be further allocated, this remaining irradiation time is set to the pixel of the group D of the fourth priority.

FIG. 17 shows the case where, to the pixel of the group A to be irradiated with the beam 1, the irradiation time of each of the pixels of the groups B and C, for example, in the same pixel-set is allocated. FIG. 17 shows the state where the irradiation time of the pixel of the group A has reached the maximum irradiation time by being allocated with the irradiation time of each of the pixels of the groups B and C in the same pixel-set. If there is an irradiation time, which is not needed to be further allocated, in the groups C and D in the same pixel-set, this irradiation time is allocated to the pixel of the group B, in the same pixel-set, to be within the range of the maximum irradiation time. If there is an irradiation time, which is not needed to be further allocated, in the group D in the same pixel-set, this irradiation time is allocated to the pixel of the group C, in the same pixel-set, to be within the range of the maximum irradiation time. If there is an irradiation time which is not needed to be further allocated, this irradiation time is set to the pixel of the group D in the same pixel-set.

Furthermore, FIG. 17 shows the case where, to the pixel of the group B to be irradiated with the beam 2, the irradiation time of the pixel of the group D, for example, in the same pixel-set is allocated. In the example of FIG. 17, since all the irradiation of the pixel of the group B, and all the irradiation of the pixel of the group C in the same pixel-set have been allocated to the irradiation time of the group A in the same pixel-set, the irradiation time allocated from the pixel of the group D in the same pixel-set is set as the irradiation time of the pixel of the group B. The irradiation time of the pixel of the group A in the same pixel-set is obtained by adding the irradiation time of each of the groups B and C in the same pixel-set to its own irradiation time of the pixel of the group A. The irradiation time of the pixel of the group C in the same pixel-set is zero because all of its own irradiation time has been allocated to the group A in the same pixel-set. The irradiation time of the pixel of the group D in the same pixel-set is also zero because all of its own irradiation time has been allocated to the group B in the same pixel-set.

Furthermore, FIG. 17 shows the case where the irradiation time of the pixel of the group C to be irradiated with the beam 3 is zero because all of its own irradiation time has been allocated to the irradiation time of the pixel of the group A in the same pixel-set, and all of the irradiation time of the pixel of the group D in the same pixel-set has been allocated to the pixel of the group B in the same pixel-set. Thus, with respect to the pixel of the group C to be irradiated with the beam 3, zero is set as the irradiation time. The irradiation time of the pixel of the group A in the same pixel-set is obtained by adding the irradiation time of each of the groups B and C in the same pixel-set to its own irradiation time of the pixel of the group A. The irradiation time of the pixel of the group B in the same pixel-set is the one allocated from the pixel of the group D in the same pixel-set. The irradiation time of the pixel of the group D in the same pixel-set is zero because all of its own irradiation time has been allocated to the group B in the same pixel-set.

Furthermore, FIG. 17 shows the case where the irradiation time of the pixel of the group D to be irradiated with the beam 4 is zero because all of its own irradiation time has been allocated to the irradiation time of the pixel of the group B in the same pixel-set. The irradiation time of the pixel of the group A in the same pixel-set is obtained by adding the irradiation time of each of the groups B and C in the same pixel-set to its own irradiation time of the pixel of the group A. The irradiation time of the pixel of the group B in the same pixel-set is the one allocated from the pixel of the group D in the same pixel-set. The irradiation time of the pixel of the group C in the same pixel-set is zero because all of its own irradiation time has been allocated to the group A in the same pixel-set.

The example of FIG. 17 describes the case where, in order of highest priority to lowest priority, allocation is performed until the irradiation time of the pixel of a group with a higher priority becomes the maximum irradiation time, it is not limited thereto. It is also preferable to perform irradiation time allocation in order of lowest priority to highest priority until the irradiation time of the pixel of a group with a higher priority becomes the maximum irradiation time. In that case, the irradiation time of the pixel of the group D whose priority is lower than other's is allocated to the pixel of the group A whose priority is higher than other's in the same pixel-set. Then, consequently, if the irradiation time of the pixel of the group A has not reached the maximum irradiation time, the irradiation time of the pixel of the group C with a second lower priority is allocated to the pixel of the group A.

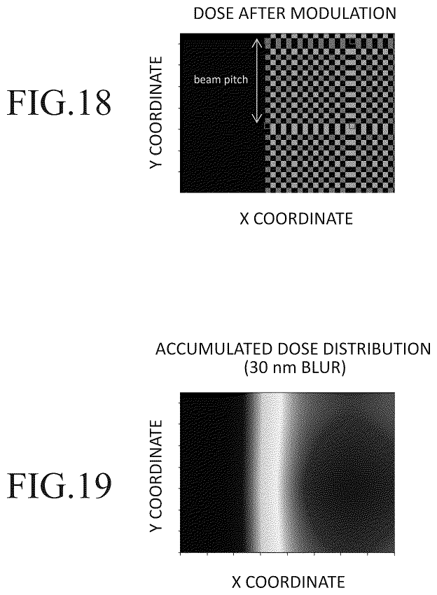

FIG. 18 is an illustration showing an example of a dose distribution after allocation according to the second embodiment.

FIG. 19 is an illustration showing an example of an accumulated dose distribution to resist after allocation according to the second embodiment.

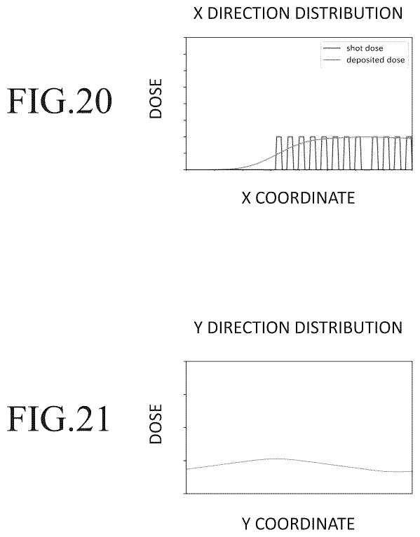

FIG. 20 is an illustration showing an example of a dose distribution in the x direction after allocation according to the second embodiment.

FIG. 21 is an illustration showing an example of a dose distribution in the y direction after allocation according to the second embodiment.

An example of the dose distribution before allocation according to the second embodiment is approximately the same as that in FIG. 10. Note that the dose of each pixel in a region with a pattern is set to 0.5 (value standardized by defining the reference dose to be 1). Although the dose of 0.5 is low, it can be used, for example, as a dose in one writing processing in multiple writing. FIGS. 10 and 18 to 21 show the cases of using 2×2 multiple electron beams 20 of the beams 1 to 4. Here, 30 nm blur is set as a synthesis of a beam blur and a resist blur. Also, shown are the cases where, before allocation, the irradiation time based on which the dose of each of the beams 1 to 4 is 0.5 (value standardized by defining the reference dose to be 1), and, after allocation, the irradiation time based on which the dose of the beam 1 of the group A is 1.5, the irradiation time based on which the dose of the beam 2 of the group B is 0.5, the irradiation time based on which the dose of the beam 3 of the group C is 0 (zero), and the irradiation time based on which the dose of the beam 4 of the group D is 0 (zero). In the dose distribution before allocation, the dose of each pixel in the portion where a pattern exits is constant at 0.5. In contrast, as shown in FIG. 18, the dose distribution shows the state where the irradiation time changes alternately with respect to each pixel by allocating all the irradiation time (dose of 0.5) to the pixel of the group A from the pixels of the groups C and D regarding 2×2 pixels adjacent to each other as one pixel-set. As shown in FIG. 19, when performing writing based on that dose distribution after allocation, the accumulated dose to the resist of the surface of the target object 101 can be almost constant. As shown in FIG. 20, the accumulated dose distribution in the x direction becomes uniform inside the pattern after it increases at the pattern edge. As shown in FIG. 21, the accumulated dose distribution in the y direction is uniform along the pattern edge.

The contents of each of the other steps are the same as those of the first embodiment.

As described above, even when allocation is performed with respect to three or more groups, as the irradiation time is allocated to the pixel of the group A with the first priority from the pixels of the groups B, C, and D, it is possible to make the ON-beam rate less than 100% from the time of starting the irradiation, and when some time passes, to make it decrease to 25%. Therefore, the average ON-beam rate during the beam irradiation from starting beam irradiation until the last beam becomes beam OFF can be decreased, and, for example, in the case of FIG. 17, it is decreased to about 25%. Thus, since the number of ON-beams can be reduced throughout the shot cycle, the entire beam current during beam irradiation can be decreased. Therefore, according to the second embodiment, it is possible to prevent or reduce a beam blur occurring due to the Coulomb effect, and prevent or reduce a resolution deterioration. Furthermore, similarly to the First embodiment, a dose difference occurring from an irradiation time difference among the groups A, B, C, and D in each pixel-set can be equalized due to an averaging effect in space such as overlapping of doses of adjacent beams. As a result, a dose difference (large or small) of pixels among the groups in each pixel-set can be eliminated.

### Third Embodiment

In each Embodiment described above, a pixel-set is composed of adjacent pixels, but it is not limited thereto. A third embodiment describes the case where a pixel-set is configured by writing processing of multiple writing. An example of the configuration of the writing apparatus in the third embodiment is the same as that of FIG. 1. The flowchart showing an example of main steps of a writing method according to the third embodiment is the same as that of FIG. 7. The contents of the third embodiment are the same as those of the first or second embodiment except for what is particularly described below.

According to the third embodiment, multiple writing by a plurality of shots is performed to each pixel 36.

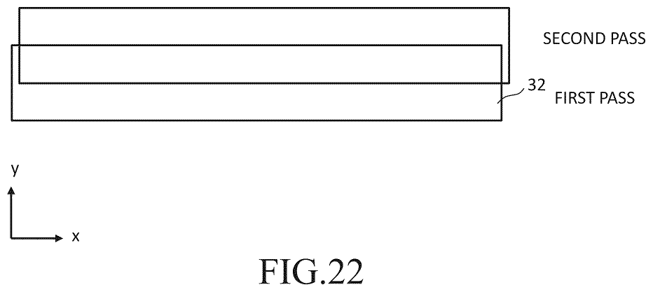

FIG. 22 is an illustration showing an example of stripe layers of passes of multiple writing (multiple pass writing) according to the third embodiment. The position of the stripe region 32 of the first pass, and that of the stripe region 32 of the second pass in multiple writing are set to be shifted from each other. For example, in the case of the multiplicity N, stripe layers are shifted from each other in the y direction by 1/N of the width of the stripe region. Alternatively, they may be shifted from each other in the x direction. The case of writing the stripe region 32 by one stage movement is defined as writing processing of one pass. The case of writing the same stripe region by repeating the stage movement N times is defined as multiple writing of N passes.

Although FIG. 22 shows the case where the stripe region 32 is shifted by a position shift amount larger than the pixel size, it is not limited thereto. The stripe region 32 may be shifted by a position shift amount smaller than the pixel size.

In the group assignment step (S100), the group assignment processing unit 56 individually assigns one of a plurality of groups A and B to a plurality of pixels 36 obtained by dividing the stripe region 32 (an example of a writing region) of the target object 101 such that pixels 36, which are preset to be in the same pixel-set, individually belong to different groups, and that pixels 36 irradiated by each shot of the multiple electron beams 20 include the pixels 36 of different groups.

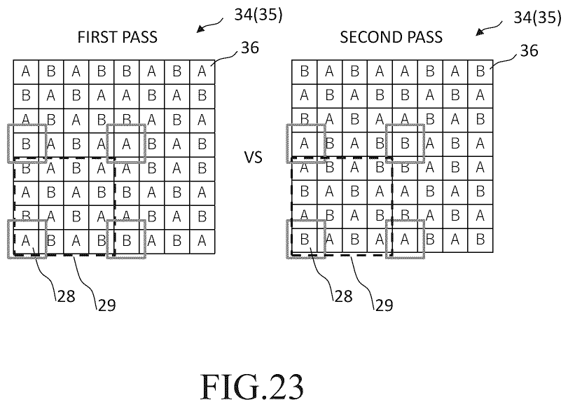

FIG. 23 is an illustration showing an example of an assignment of a group to a pixel according to the third embodiment.

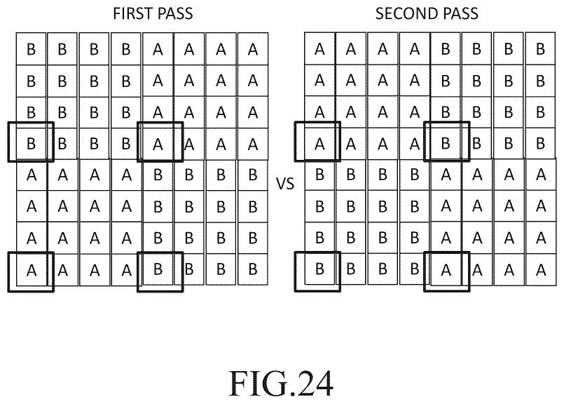

FIG. 24 is an illustration showing another example of an assignment of a group to a pixel according to the third embodiment.

In the examples of FIGS. 23 and 24, a pixel-set is composed of pixels 36 whose at least a part of regions are overlapped with each other in each writing processing of multiple writing. If the pixel of each pass is the same pixel in two pass writing, group assignment is performed, for example, such that the pixel belonging to the group A in the writing processing of the first pass belongs to the group B in the writing processing of the second pass. Similarly, for example, group assignment is performed such that the pixel belonging to the group B in the writing processing of the first pass belongs to the group A in the writing processing of the second pass. If the pixel of each pass is not the same pixel in two pass writing, such as if the position of the pixel of the second pass is shifted in the x and y directions by a half of the pixel size from the pixel of the first pass, it is also possible to perform group assignment to each pixel as shown in FIGS. 23 and 24.

Group assignment is performed such that a plurality of pixels 28 to be irradiated with each shot of the multiple electron beams 20 include those of different groups. FIGS. 23 and 24 show the case where group assignment is performed such that beams adjacent in the x and y directions of 2×2 multiple electron beams 20 irradiate the pixels 28 of different groups.

FIG. 23 shows, similarly to FIG. 8, the case where a plurality of groups are individually assigned to be alternate each other in both the x and y directions. However, the group assignment is not limited to that case. It is also preferable as shown in FIG. 24 to assign each group per sub-irradiation region 29, for example, to be alternate each other in both the x and y directions.

According to the third embodiment, since averaging is performed between passes of multiple writing, it is not necessary that the groups of adjacent pixels are different from each other.

The contents of each subsequent step are the same as those of the first embodiment.

As described above, according to the third embodiment, even when a pixel-set is configured by passes of multiple writing, it is possible, similarly to the first or second embodiment, to reduce an average ON-beam rate during beam irradiation. Accordingly, the Coulomb effect can be reduced.

### Fourth Embodiment

In each Embodiment described above, an irradiation time as much as possible, within the range of the maximum irradiation time, is allocated to, for example, the group A being one of a plurality of groups in the same pixel-set, but it is not limited thereto. According to a fourth embodiment, the irradiation time (dose) between groups in the same pixel-set is controlled to be close to a predetermined ratio. An example of the configuration of the writing apparatus in the fourth embodiment is the same as that of FIG. 1. The flowchart showing an example of main steps of a writing method according to the fourth embodiment is the same as that of FIG. 7. The contents of the fourth embodiment are the same as those of at least one of the first to third embodiments except for what is particularly described below.

In the allocation step (S120), the allocation unit 58 performs allocation, with respect to each pixel-set, in order that the irradiation time of the pixel 36 to which the group A of a plurality of groups has been assigned can be longer than the irradiation time of the pixel 36 to which another group in the same pixel-set has been assigned, in such a manner that at least a part of the irradiation time of the pixel 36 to which the another group, the group B, has been assigned is allocated to the irradiation time of the pixel 36 to which the group A has been assigned.

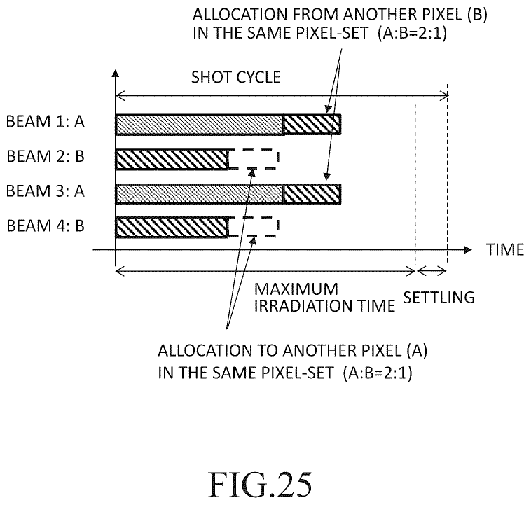

FIG. 25 is an illustration showing an example of an irradiation time of one shot of multiple electron beams according to the fourth embodiment. In the fourth embodiment, the multiple electron beams 20 are applied based on a counter system which controls the irradiation time of each beam. FIG. 25 shows the case of using 2×2 multiple electron beams 20 of beams 1 to 4. In the example of FIG. 25, a certain shot applies beams 1 and 3, located diagonally, to the pixels of the group A, and beams 2 and 4, located diagonally, to the pixels of the group B.

FIG. 25 shows the case where, before allocation, the dose of each beam is the same value. In the example of FIG. 25, the dose or the irradiation time of each pixel 36 in each pixel-set is set so that the ratio of the dose or of the irradiation time between the pixel 36, to which the group A of a plurality of groups A and B has been assigned, and the pixel, to which the group B in the same pixel-set has been assigned, can be close to a preset ratio. For example, the dose or the irradiation time of each pixel 36 in each pixel-set is set such that the ratio of the dose or of the irradiation time between the pixel 36, to which the group A of a plurality of groups A and B has been assigned, and the pixel, to which the group B in the same pixel-set has been assigned, becomes a preset ratio.

With respect to the pixel of the group A to be irradiated with the beam 1, a part of the irradiation time is allocated from the pixel of the group B in the same pixel-set. In the example of FIG. 25, in order that the irradiation time (or dose) of the pixel of the group A may be twice the irradiation time (or dose) of the group B in the same pixel-set, the irradiation time (or dose) of the group B in the same pixel-set is allocated. FIG. 25 shows the case where the irradiation time equivalent to ¼ of the irradiation time of the pixel of the group A is allocated from the pixel of the group B in the same pixel-set. Therefore, in the same pixel-set, the ratio is (group A):(group B)=2:1.

With respect to the pixel of the group B to be irradiated with the beam 2, its partial irradiation time is allocated to the pixel of the group A in the same pixel-set. In the example of FIG. 25, in order that the irradiation time (or dose) of the pixel of the group B may be ½ of the irradiation time (or dose) of the group A in the same pixel-set, the irradiation time (or dose) is allocated to the pixel of the group A in the same pixel-set. FIG. 25 shows the case where the irradiation time equivalent to ¼ of the irradiation time of the pixel of the group B is allocated to the pixel of the group A in the same pixel-set. Therefore, in the same pixel-set, the ratio is (group A):(group B)=2:1.

With respect to the pixel of the group A to be irradiated with the beam 3, a part of the irradiation time is allocated from the pixel of the group B in the same pixel-set. In the example of FIG. 25, in order that the irradiation time (or dose) of the pixel of the group A may be twice the irradiation time (or dose) of the group B in the same pixel-set, the irradiation time (or dose) of the group B in the same pixel-set is allocated. FIG. 25 shows the case where the irradiation time equivalent to ¼ of the irradiation time of the pixel of the group A is allocated from the pixel of the group B in the same pixel-set. Therefore, in the same pixel-set, the ratio is (group A):(group B)=2:1.

With respect to the pixel of the group B to be irradiated with the beam 4, its partial irradiation time is allocated to the pixel of the group A in the same pixel-set. In the example of FIG. 25, in order that the irradiation time (or dose) of the pixel of the group B may be ½ of the irradiation time (or dose) of the group A in the same pixel-set, the irradiation time (or dose) is allocated to the pixel of the group A in the same pixel-set. FIG. 25 shows the case where the irradiation time equivalent to ¼ of the irradiation time of the pixel of the group B is allocated to the pixel of the group A in the same pixel-set. Therefore, in the same pixel-set, the ratio is (group A):(group B)=2:1.

There may be a case where a preset ratio cannot be obtained because, for example, the irradiation time of the pixel of the group A has reached the maximum irradiation time due to being added with a part of an allocation amount. In such a case, it is sufficient to perform allocation to be as close as possible to a preset ratio.

The above example describes the case where allocation is performed based on the same ratio for all the pixel-sets, but it is not limited thereto. It is acceptable that the ratio is variable for each pixel-set.

As described above, since the irradiation time is allocated to the pixel of the group A from the pixel of the group B, although the ON-beam rate may be 100% from the time of starting irradiation, it is possible to decrease the ON-beam rate to 50% in the middle of the irradiation. Therefore, compared with before allocation, the state of a low average ON-beam rate during beam irradiation can be lengthened. Particularly, when performing group assignment, for each pixel-set, in each writing processing of multiple writing as described in the third Embodiment, since the irradiation time does not become zero in each writing processing, it is possible not to hinder the averaging of deviations of beam irradiation positions originally being effects of multiple writing, and/or averaging of errors of current amounts between beams.

The contents of each subsequent step are the same as those of the first embodiment.

As described above, according to the fourth embodiment, a period for reducing the ON-beam rate in a beam irradiation period can be generated. Therefore, the average ON-beam rate can be decreased. Consequently, the Coulomb effect during that period can be reduced.

### Fifth Embodiment

In each Embodiment described above, allocation can be performed only up to a preset maximum irradiation time, but it is not limited thereto. A fifth embodiment describes a configuration which further increases an allocation amount. An example of the configuration of the writing apparatus in the fifth embodiment is the same as that of FIG. 1. The flowchart showing an example of main steps of a writing method according to the fifth embodiment is the same as that of FIG. 7. The contents of the fifth embodiment are the same as those of at least one of the first to fourth embodiments except for what is particularly described below.

In the allocation step (S120), the allocation unit 58 performs allocation, with respect to each pixel-set, in order that the irradiation time of the pixel 36 to which the group A of a plurality of groups has been assigned can be longer than the irradiation time of the pixel 36 to which another group in the same pixel-set has been assigned, in such a manner that at least a part of the irradiation time of the pixel 36 to which the another group, the group B, has been assigned is allocated to the irradiation time of the pixel 36 to which the group A has been assigned.

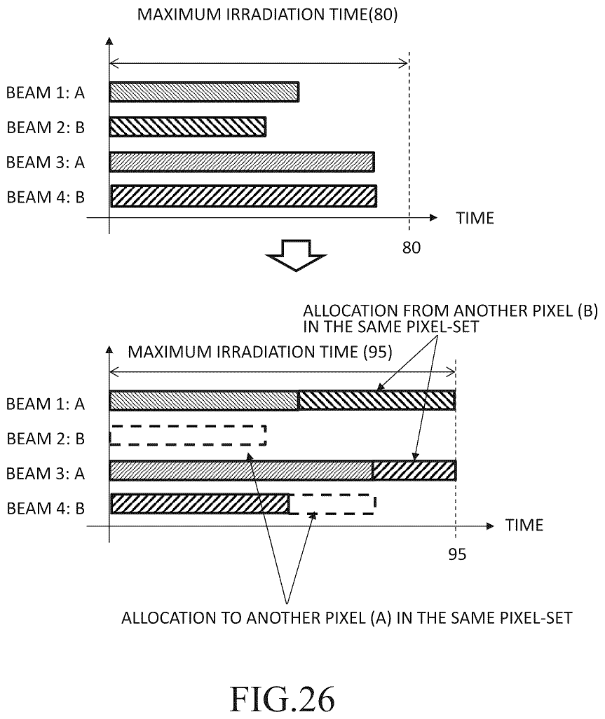

FIG. 26 is an illustration showing an example of an irradiation time of one shot of multiple electron beams according to the fifth embodiment. In the fifth embodiment, the multiple electron beams 20 are applied based on a counter system which controls the irradiation time of each beam. FIG. 26 shows the case of using 2×2 multiple electron beams 20 of beams 1 to 4. In the example of FIG. 26, a certain shot applies beams 1 and 3, located diagonally, to the pixels of the group A, and beams 2 and 4, located diagonally, to the pixels of the group B.

FIG. 26 shows the case where, before allocation, at least one of the doses of respective beams is a long irradiation time close to the maximum irradiation time (80). For example, if the irradiation time of the pixel of the group A which receives allocation is, from the first, the maximum irradiation time or close to the maximum irradiation time, the irradiation time which can be allocated from the pixel of the group B in the same pixel-set becomes short, thereby making the period for reducing ON-beams become short. Then, in the example of FIG. 26, the preset maximum irradiation time itself is extended. FIG. 26 shows the case where the maximum irradiation time itself is extended from 80 to 95. Therefore, the irradiation time which can be allocated from the pixel of the group B in the same pixel-set can be increased.

With respect to the pixel of the group A to be irradiated with the beam 1, at least partial irradiation time is allocated from the pixel of the group B in the same pixel-set. In the example of FIG. 26, by extending the maximum irradiation time itself from 80 to 95, all the irradiation time, being within the range of an extended maximum irradiation time, of the pixel of the group B in the same pixel-set can be allocated to the pixel of the group A, for example.

With respect to the pixel of the group B to be irradiated with the beam 2, its at least partial irradiation time is allocated to the pixel of the group A in the same pixel-set. In the example of FIG. 26, by extending the maximum irradiation time itself from 80 to 95, all of its own irradiation time is allocated to the pixel of the group A in the same pixel-set, and therefore, the irradiation time of the pixel of the group B has become zero.

With respect to the pixel of the group A to be irradiated with the beam 3, at least partial irradiation time is allocated from the pixel of the group B in the same pixel-set. In the example of FIG. 26, by extending the maximum irradiation time itself from 80 to 95, all the irradiation time, being within the range of an extended maximum irradiation time, of the pixel of the group B in the same pixel-set can be allocated to the pixel of the group A, for example.

With respect to the pixel of the group B to be irradiated with the beam 4, its at least partial irradiation time is allocated to the pixel of the group A in the same pixel-set. In the example of FIG. 26, by extending the maximum irradiation time itself from 80 to 95, a more irradiation time, compared with the one before extending the maximum irradiation time, can be allocated to the pixel of the group A in the same pixel-set. A remaining irradiation time which is not needed to be further allocated is set to the pixel of the group B. In connection with extending the maximum irradiation time, the stage speed at the time of writing is made slow according to the extended time.

The contents of each subsequent step are the same as those of the first embodiment.

As described above, according to the fifth embodiment, by extending the maximum irradiation time, the period for reducing the ON-beam rate during beam irradiation can be lengthened. Therefore, the average ON-beam rate can be decreased. Consequently, the Coulomb effect during that period can be reduced.

Embodiments have been explained referring to specific examples described above. However, the present invention is not limited to these specific examples. Although the examples described above describe the case where only a proximity effect is corrected, it is not limited thereto.

While the apparatus configuration, control method, and others not directly necessary for explaining the present invention are not described, some or all of them can be appropriately selected and used on a case-by-case basis when needed. For example, although description of the configuration of the control unit for controlling the writing apparatus 100 is omitted, it should be understood that some or all of the configuration of the control unit can be selected and used appropriately when necessary.

Furthermore, any other multi-charged particle beam writing method, and multi-charged particle beam writing apparatus that include elements of the present invention and that can be appropriately modified by those skilled in the art are included within the scope of the present invention.

Additional advantages and modification will readily occur to those skilled in the art. Therefore, the invention in its broader aspects is not limited to the specific details and representative embodiments shown and described herein. Accordingly, various modifications may be made without departing from the spirit or scope of the general inventive concept as defined by the appended claims and their equivalents.

What is claimed is:

1. A multi-charged particle beam writing method comprising:
assigning one of a plurality of groups to each of a plurality of irradiation unit regions, which are unit regions to be irradiated with each beam of multiple charged particle beams, obtained by dividing a writing region of a target object, in such a manner that irradiation unit regions, which are in advance set to form a same irradiation-unit-region-set of a plurality of irradiation-unit-region-sets, belong to different groups, and that irradiation unit regions to be irradiated with each shot of the multiple charged particle beams include irradiation unit regions of different groups;
performing allocation, with respect to each irradiation-unit-region-set of the plurality of irradiation-unit-region-sets, in order that one of a dose and an irradiation time of an irradiation unit region to which one group of the plurality of groups has been assigned can become more than one of a dose and an irradiation time of an irradiation unit region, in a same irradiation-unit-region-set, to which another group of the plurality of groups has been assigned, in such a manner that at least a part of the one of the dose and the irradiation time of the irradiation unit region to which the another group has been assigned is allocated to the irradiation unit region to which the one group has been assigned; and
writing a pattern on the target object using the multiple charged particle beams in such a manner that the plurality of irradiation unit regions are irradiated with a charged particle beam having one of a dose and an irradiation time defined by the allocation.

2. The method according to claim 1, wherein each irradiation-unit-region-set of the plurality of irradiation-unit-region-sets is composed of irradiation unit regions adjacent to each other.

3. The method according to claim 1, wherein
multiple writing by a plurality of shots is performed to each of the plurality of irradiation unit regions, and
each irradiation-unit-region-set of the plurality of irradiation-unit-region-sets is composed of irradiation unit regions whose at least a part of regions are overlapped with each other in each writing processing of the multiple writing.

4. The method according to claim 1, wherein one of a preset maximum dose and a preset maximum irradiation time is set to the irradiation unit region to which the one group of the plurality of groups has been assigned.

5. The method according to claim 1, wherein one of a dose and an irradiation time of each irradiation unit region in each irradiation-unit-region-set is set such that a ratio of one of a dose and an irradiation time between the irradiation unit region to which the one group of the plurality of groups has been assigned, and the irradiation unit region to which the another group, in the same irradiation-unit-region-set, of the plurality of groups has been assigned becomes a preset ratio.

6. A multi-charged particle beam writing apparatus comprising:
a group assignment processing circuit configured to assign one of a plurality of groups to each of a plurality of irradiation unit regions, which are unit regions to be irradiated with each beam of multiple charged particle beams, obtained by dividing a writing region of a target object, in such a manner that irradiation unit regions, which are in advance set to form a same irradiation-unit-region-set of a plurality of irradiation-unit-region-sets, belong to different groups, and that irradiation unit regions to be irradiated with each shot of the multiple charged particle beams include irradiation unit regions of different groups;
an allocation circuit configured to perform allocation, with respect to each irradiation-unit-region-set of the plurality of irradiation-unit-region-sets, in order that one of a dose and an irradiation time of an irradiation unit region to which one group of the plurality of groups has been assigned can become more than one of a dose and an irradiation time of an irradiation unit region, in a same irradiation-unit-region-set, to which another group of the plurality of groups has been assigned, in such a manner that at least a part of the one of the dose and the irradiation time of the irradiation unit region to which the another group has been assigned is allocated to the irradiation unit region to which the one group has been assigned; and
a writing mechanism configured to write a pattern on the target object using the multiple charged particle beams in such a manner that the plurality of irradiation unit regions are irradiated with a charged particle beam having one of a dose and an irradiation time defined by the allocation.
